(19) United States
(12) Patent Application Publication
(10) Pub. No.: US 2007/0275542 A1
(43) Pub. Date: Nov. 29, 2007

(54) SUBSTRATE SEPARATION METHOD AND LIQUID EJECTING HEAD PRODUCTION METHOD USING THE SUBSTRATE SEPARATION METHOD

(75) Inventor: Wataru Takahashi, Chino-shi (JP)

Correspondence Address: WORKMAN NYDEGGER, 60 EAST SOUTH TEMPLE, 1000 EAGLE GATE TOWER, SALT LAKE CITY, UT, 84111, US

(73) Assignee: SEIKO EPSON CORPORATION, Tokyo (JP)

(21) Appl. No.: 11/752,782

(22) Filed: May 23, 2007

(30) Foreign Application Priority Data
May 23, 2006 (JP) 2006-143258

(51) Int. Cl. H01L 21/00

(52) U.S. Cl. 438/460

(57) ABSTRACT

The invention provides a substrate separation method for separating a substrate into a plurality of chips. The substrate separation method according to the invention includes: a first step of irradiating a laser beam on boundary lines of each area, which constitutes a chip, of the substrate, while concentrating the beam at a convergence point inside the substrate; a second step of forming fragile parts with a predetermined width in the substrate while leaving connecting parts only at a surface layer of the substrate at a laser beam irradiation side; and a third step of separating the substrate into the plurality of chips along the fragile parts by applying an external force to the substrate.

The entire disclosure of Japanese Patent Application No. 2006-143258, filed May 23, 2006 is expressly incorporated by reference herein.

### BACKGROUND

1. Technical Field

The present invention relates to a substrate separation method for separating a substrate into a plurality of chips, and to a liquid ejecting head production method that uses the substrate separation method.

2. Related Art

As an example of related art, a liquid ejecting head that discharges droplets via a nozzle orifice thereof when pressure is applied to a liquid contained inside a pressure generation chamber by pressure generation means such as a piezoelectric element, and so on, is known, where a typical example of such a liquid ejecting head is an ink jet type recording head that discharges ink drops as droplets. Further, as a known configuration of such an ink jet type recording head, pressure generation means such as piezoelectric elements is provided at one surface of a fluid channel formation substrate having pressure generation chambers formed inside the fluid channel formation substrate, and a nozzle plate through which nozzle orifices are bored is bonded at the other surface of the fluid channel formation substrate.

A silicon single crystal substrate, for example, is employed as a material of such a fluid channel formation substrate that constitutes an ink jet type recording head. Generally, fluid channel formation substrates as described above are manufactured by, firstly, forming a plurality of pre-separation fluid channel formation substrates on a substrate such as a silicon wafer as a single piece as a whole, and then by separating each fluid channel formation substrate from others.

As an example of a substrate separation method disclosed in JP-A-2002-313754, a “break pattern” is formed on cutting plane lines each of which runs between a pre-separation fluid channel formation substrate (i.e. chip) and another adjacent pre-separation fluid channel formation substrate formed on a silicon wafer (i.e. substrate), where the break pattern consists of a plurality of through holes bored at predetermined intervals, and the silicon wafer is then broken into a plurality of pieces along the break pattern when an external force is applied to the silicon wafer. When such a substrate separation method is applied to the production of a head so as to separate a silicon wafer, a fragile part lying between each one through hole and next one that constitute a break pattern as a whole is broken when an external force is applied thereto, and as a result thereof, a plurality of fluid channel formation substrates (i.e. chips) are formed.

As described above, with a break pattern provided in a silicon wafer, it is possible to separate such a silicon wafer into a plurality of fluid channel formation substrates in a relatively easy manner. However, there are some disadvantages in such a method that it is difficult to make the breaking position and the shape of a broken surface section of a silicon wafer (a fragile part) uniform, and further, there occurs a problem in that any undesirable part, which is not intended to be broken, other than a fragile part between one through hole and another adjacent through hole of the silicon wafer could be broken. In addition, there is another problem of possible cracks that could occur, originating from the corner of a through hole, on a fluid channel formation substrate that constitutes a product.

As a particular problem pertaining to the production of a liquid ejecting head such as an ink jet type recording head, depending on the state of breakage, some minute break particles could be formed from the broken surface section, and the minute break particles could settle inside the fluid channel, which causes the nozzle to be clogged. As another possible problem, if any fine break particle adheres to a fluid channel substrate, when forming a thin film, etc., on the fluid channel substrate, poor formation of the film could lower a production yield rate thereof.

### SUMMARY

An advantage of some aspects of the invention is to provide a substrate separation method which makes it possible to separate a substrate into a plurality of chips with a high performance/quality and to prevent any broken or cracked particle of each chip from adhering to the chip.

In order to provide a solution to the above-identified problems among all problems addressed by the invention, the invention provides, as a first aspect thereof, a substrate separation method for separating a substrate into a plurality of chips. Herein, the substrate separation method according to the invention includes: a first step of irradiating a laser beam on boundary lines of each area, which constitutes a chip, of the substrate, while concentrating the beam at a convergence point inside the substrate; a second step of forming fragile parts with a predetermined width in the substrate while leaving connecting parts only at a surface layer of the substrate at a laser beam irradiation side; and a third step of separating the substrate into the plurality of chips along the fragile parts by applying an external force to the substrate.

According to the first aspect of the invention, it is possible to separate the substrate in a relatively easy manner with a good performance/quality along the fragile parts. In addition, it is also possible to prevent any crack, etc., from occurring in a chip, which constitutes a product, when separating the substrate.

In the substrate separation method according to the first aspect of the invention, it is preferable that, in the second step, the fragile parts are formed in a serial manner along the boundary lines of each area, which constitutes a chip.

With such a configuration, it is possible to separate the substrate along the fragile parts without fail, and also to provide very smooth broken surfaces (side surfaces of each chip).

In the substrate separation method according to the first aspect of the invention, it is preferable that, in the second step, the fragile parts are formed in an intermittent manner along the boundary lines of each area, which constitutes a chip.

With such a configuration, each chip is more securely linked and connected to other chips adjacent thereto on a pre-separation substrate, whereas it is possible to separate the substrate in a relatively easy manner with a good performance/quality by applying an external force thereto.

In the substrate separation method according to the first aspect of the invention, it is preferable that, in the second step, the fragile parts are formed such that the thickness of the connecting part is 30 μm or less.

With such a configuration, since the thickness of the connecting part is relatively thin, it is possible to separate the substrate in a further easier manner with a better performance/quality.

In the substrate separation method according to the first aspect of the invention, it is preferable that, in the second step, the fragile parts are formed such that the width of the fragile part is 15 μm or less.

With such a configuration, since the fragile part is formed to have a relatively narrow width, it is possible to provide very smooth broken surface in a more reliable manner.

In the substrate separation method according to the first aspect of the invention, it is preferable that, in the second step, the fragile parts are formed by scanning the laser beam on the boundary lines a plural number of times while changing the position of the convergence point in a thickness direction of the substrate.

With such a configuration, it is possible to form a fragile part having a relatively narrow width with a good performance/quality, and it is also possible to prevent any adverse effects on the peripheral part around the fragile part on the substrate.

The invention provides, as a second aspect thereof, a method for producing a liquid ejecting head, the liquid ejecting head having a fluid channel formation substrate in which pressure generation chambers, each of which is communicated with a nozzle and which applies pressure for ejecting droplets from the nozzle, are formed. Herein, the liquid ejecting head production method according to the invention includes: forming a plurality of the fluid channel formation substrates on a fluid channel formation substrate wafer as a single piece as a whole; and, after formation thereof, separating the fluid channel formation substrate wafer into a plurality of the fluid channel formation substrates according to the substrate separation method as set forth in the first aspect of the invention.

With such a configuration, it is possible to prevent any minute break particle (foreign object), which might be formed during separation of the fluid channel formation substrate wafer, from adhering to the substrate. In particular, the invention prevents any foreign object from settling in the fluid channel such as the pressure generation chamber, which makes it possible to further prevent the nozzle from being clogged. It should be noted that, even in a case where such a crack particle settles inside the fluid channel, since the size of a crack particle is very small, it is possible to easily drain the particle from the nozzle by, for example, washing in the fluid channel.

### BRIEF DESCRIPTION OF THE DRAWINGS

The invention will be described with reference to the accompanying drawings, wherein like numbers reference like elements.

FIGS. 1A and 1B is a set of sectional views that schematically illustrates an example of an ink jet type recording head.

FIG. 2 is a plane view of an example of a fluid channel formation substrate that constitutes an ink jet type recording head.

FIGS. 3A and 3B are a plane view and a sectional view that schematically illustrate an example of a wafer for fluid channel formation substrates, respectively.

FIGS. 4A and 4B are sectional views of a fluid channel formation substrate wafer that exemplify a substrate separation method according to an embodiment of the invention.

FIGS. 5A, 5B, and 5C are sectional views of a fluid channel formation substrate wafer that exemplify a substrate separation method according to an embodiment of the invention.

FIG. 6 is a plane view of an example of a fluid channel formation substrate wafer that schematically illustrates another example of fragile parts.

FIGS. 7A, 7B, and 7C are schematic diagrams that explain another example of a substrate separation method according to an embodiment of the invention.

### DESCRIPTION OF EXEMPLARY EMBODIMENTS

The present invention is described below while explaining exemplary embodiments thereof.

### Embodiment 1

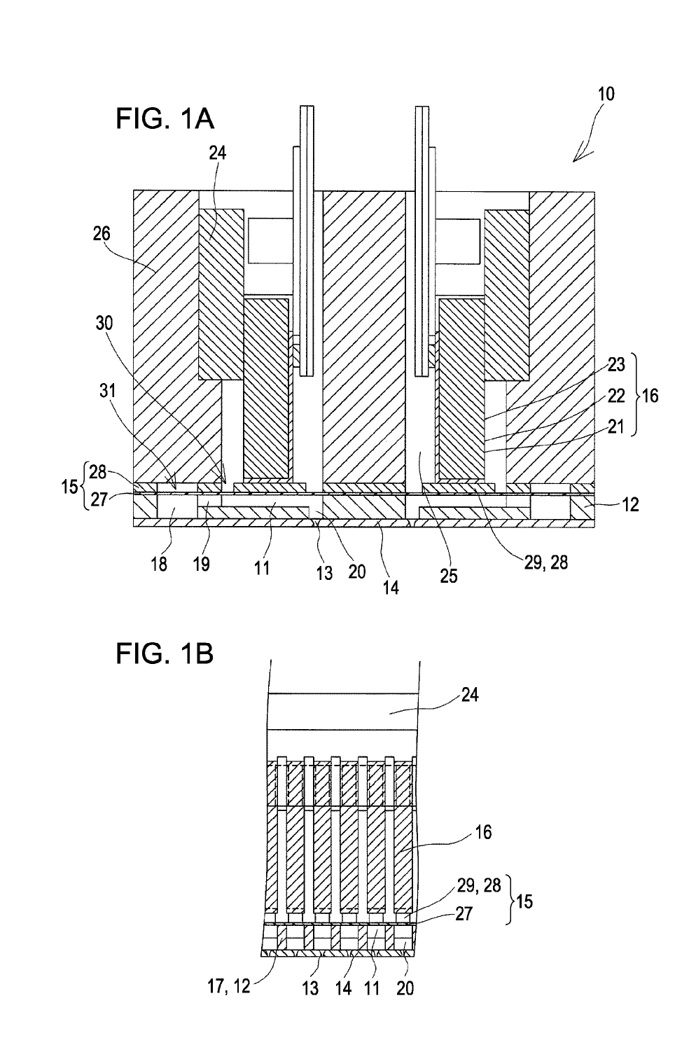

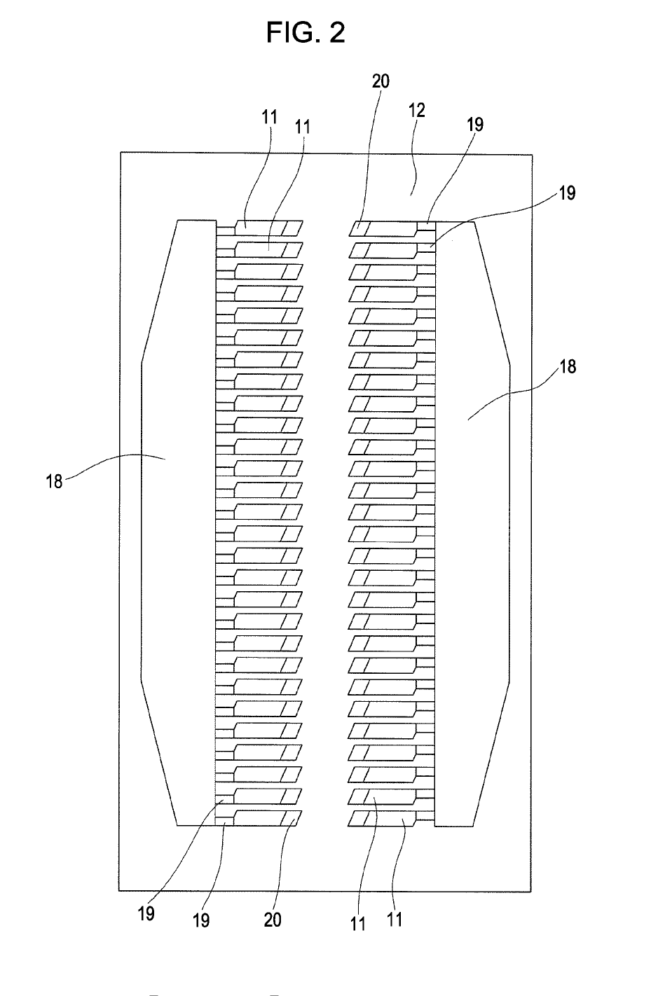

In this embodiment, a substrate separation method according to the invention is explained while exemplifying an ink jet type recording head as an example of a liquid ejecting head. Note that FIGS. 1A and 1B is a set of sectional views illustrating an example of an ink jet type recording head, and FIG. 2 is a plane view illustrating a fluid channel formation substrate.

As illustrated in these figures, an ink jet type recording head 10 has a fluid channel formation substrate 12, which is provided with a plurality of pressure generation chambers 11, a nozzle plate 14, which a plurality of nozzle orifices 13 are bored through, where each nozzle orifice 13 is communicated with a corresponding pressure generation chamber 11, a vibrating plate 15, which is provided on a surface of the fluid channel formation substrate 12 opposite to the other surface at which the nozzle plate 14 is provided, and piezoelectric elements 16, each of which is provided at a space over the vibrating plate 15 corresponding to the pressure generation chamber 11.

At a surface layer part of one face of the fluid channel formation substrate 12, each of a plurality of the pressure generation chambers 11 is provided in the across-the-width direction, where the pressure generation chambers 11 are sectioned by partitions 17. For example, in this embodiment of the invention, two columns of the plurality of the pressure generation chambers 11 are provided in parallel with each other on the fluid channel formation substrate 12. A reservoir 18 for supplying ink to each of the plurality of the pressure generation chambers 11 is provided outside each column of the pressure generation chambers 11 by penetrating through the fluid channel formation substrate 12 in the thickness direction. Each of the pressure generation chambers 11 is communicated with the reservoir 18 through an ink supply path 19, which is an example of a liquid supply path. In this embodiment of the invention, the ink supply path 19 is formed in such a manner that the ink supply path 19 has a width narrower than the pressure generation chamber 11 so as to serve a function of maintaining the fluid channel resistance of ink that flows into the pressure generation chamber 11 from the reservoir 18 at a constant level. In addition, at the other end portion of each of the pressure generation chamber 11 opposite to the reservoir 18, a nozzle communication hole 20 is bored through the fluid channel formation substrate 12. It should be noted that, in this embodiment of the invention, the fluid channel formation substrate 12 configured as described above is made a surface of a silicon single crystal substrate having a plane orientation (110), and the pressure generation chamber 11, etc., is formed by performing anisotropic etching on the fluid channel formation substrate 12. Accordingly, the pressure generation chamber 11 is configured to have a first surface (111) plane that is perpendicular to the surface (110) plane at its long side, and a second surface (111) plane that is perpendicular to the surface (110) plane and intersects with the first surface (111) plane at a predetermined angle at its short side.

On one surface of the fluid channel formation substrate 12, the nozzle plate 14 through which the nozzle orifices 13 are bored is bonded by means of an adhesive or a heat deposition film, where each of the nozzle orifices 13 is communicated with corresponding one of the pressure generation chambers 11 via corresponding one of the nozzle communication holes 20. On the other hand, the vibrating plate 15 is bonded at the other surface of the fluid channel formation substrate 12, that is, at the opening surface of the pressure generation chamber 11 in such a manner that the vibrating plate 15 seals each of the pressure generation chambers. The piezoelectric element 16, which is pressure generation means for generating pressure in the pressure generation chamber 11 for discharging ink drops, is fixed in such a state that the tip of the piezoelectric element 16 contacts the vibrating plate 15. More specifically, the piezoelectric element 16 consists of an active region that functions to cause vibration and an inactive region that does not function to cause vibration, where the tip of the active region contacts the vibrating plate 15.

The piezoelectric element 16 according to this embodiment of the invention is a so-called vertical-vibration-type piezoelectric element, where the piezoelectric element 16 is configured as a lamination of a piezoelectric material 21 and electrode formation materials 22 and 23 placed vertically in a sandwich pattern in an alternate order; and the inactive region that does not function to cause vibration is fixed to a fixing substrate 24. In addition, in this embodiment of the invention, head cases 26 are fixed on the vibrating plate 15, where each of the head case 26 has a piezoelectric-element-holding part 25 that allows an open space, which is unoccupied enough not to hinder the movement of the piezoelectric element 16, to be covered. Moreover, the fixing substrate 24, which the piezoelectric element 16 is fixed to, is fixed to the head case 26 on a side opposite to the piezoelectric element 16 side.

Herein, the vibrating plate 15, which the tip of the piezoelectric element 16 contacts, is made of a composite plate that consists of an elastic membrane made of an elastic member such as a resin film, and a supporting plate 28 made of a metal material and so on for supporting the elastic membrane 27, where the elastic membrane 27 side of the vibrating plate 15 is bonded to the fluid channel formation substrate 12. For example, in this embodiment of the invention, the elastic membrane 27 is made of a polyphenylene sulfide (PPS) film having a thickness of approximately a few micrometers (μm), whereas the supporting plate 28 is made of a stainless steel (SUS) plate having a thickness of approximately dozens of micrometers. On each area of the vibrating plate 15 opposite to corresponding one of the pressure generation chambers 11, an island part 29 where the tip of each piezoelectric element 16 contacts is provided. That is, a thin part 30 having a thickness smaller than that of other areas is formed at an area of the vibrating plate 15 corresponding to each end part of each pressure generation chamber 11, whereas each island part 29 is formed inside the thin part 30. For example, in this embodiment of the invention, the island parts 29 and thin parts 30 of the vibrating plate 15 are formed by etching away the supporting plate 28; and the thin part 30 is substantially constituted by the elastic membrane 27 only, the detailed explanation of which will be provided later. As have already been described, each of the piezoelectric element 16 is fixed in such a manner that the tip of the active region thereof contacts the island part 29 of the vibrating plate 15 configured as above. In addition, in this embodiment of the invention, a compliance part 31, which is, likewise the thin part 30, substantially constituted by an elastic member only after the supporting plate 28 has been etched away is provided at an area of the vibrating plate 15 opposite to the reservoir 18. Note that the compliance part 31 functions to keep pressure inside the reservoir 18 at a constant level by absorbing any pressure change when such a change occurs in the reservoir 18, which is achieved by deformation of the elastic member 27 of the compliance part 31.

When discharging ink drops, the ink jet type recording head 10 as described above is configured to change the volume of each of the pressure generation chambers 11 through deformation of the piezoelectric element 16 and the vibrating plate 15, thereby discharging ink drops through the predetermined nozzle orifice 13. More specifically, when ink is supplied from a liquid reserve body such as an ink cartridge not shown in the figure to the reservoir 18 via an ink fluid channel, not shown in the figure, which is formed inside the head case 26, the ink is then distributed to each of the pressure generation chambers 11 via corresponding one of the ink supply path 19. In practical implementation, the piezoelectric element 16 is subjected to voltage application for contraction thereof. With the contraction of the piezoelectric element 16, the vibrating plate 15 as well as the piezoelectric element 16 is deformed to increase the volume of the pressure generation chamber 11, thereby causing the ink to be drawn into the pressure generation chamber 11. After the completion of the filling of ink up to the nozzle orifice 13, in response to a recording signal sent from a driving circuit, a voltage applied to the electrode formation materials 22 and 23 of the piezoelectric element 16 is released. When it is released, the piezoelectric element 16 expands and reverts to its original state, and in addition thereto, the vibrating plate 15 is also displaced to return to its original state. As a result thereof, the volume of the pressure generation chamber 11 becomes smaller through contraction so as to heighten pressure inside the pressure generation chamber 11, thereby discharging ink drops through the nozzle orifice 13.

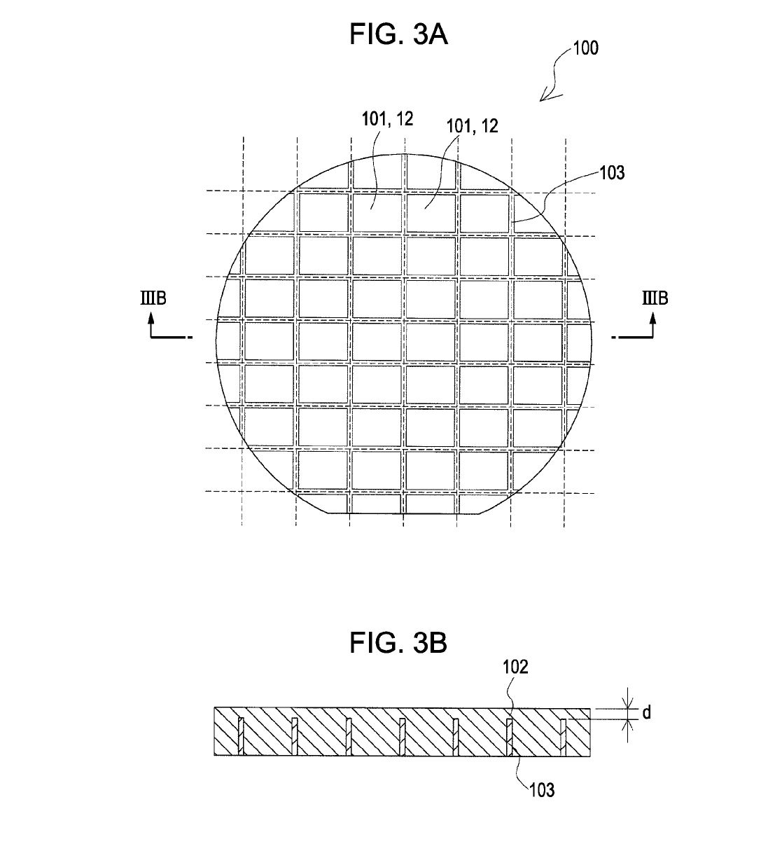

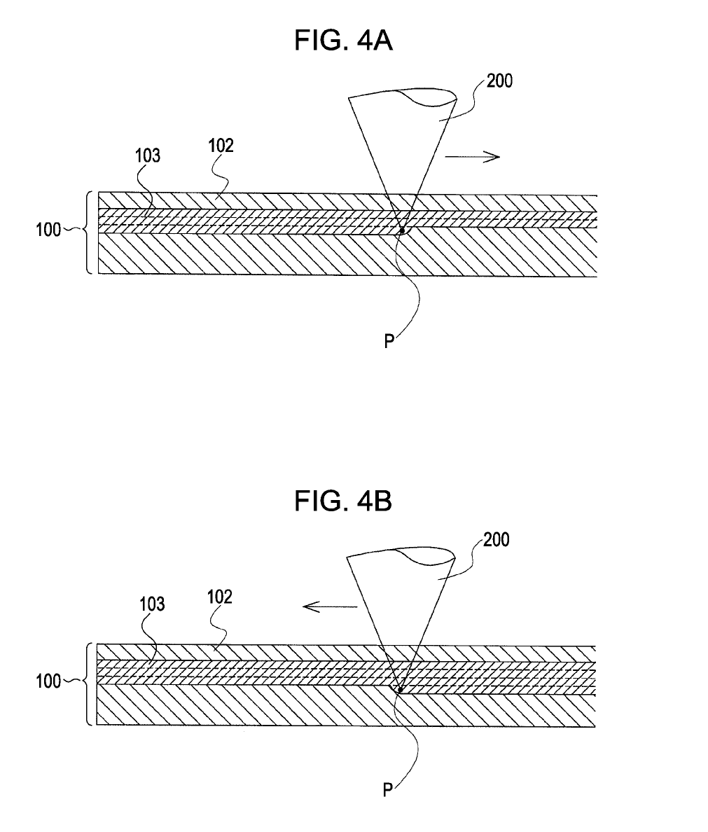

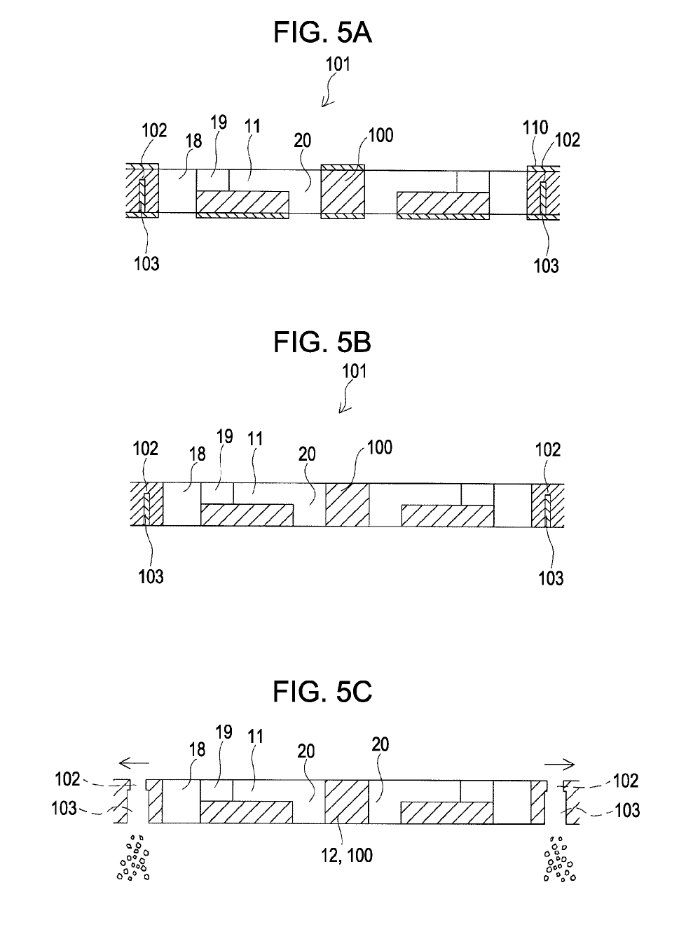

In the following description, a method for producing a fluid channel formation substrate that constitutes an ink jet type recording head as described above, or more specifically, a method for separating a fluid channel formation substrate wafer is explained below. FIGS. 3A and 3B are a plane view and a sectional view illustrating an example of a wafer for fluid channel formation substrates, respectively, while FIGS. 4A and 4B as well as FIGS. 5A, 5B, and 5C are sectional views of a fluid channel formation substrate wafer that exemplify a substrate separation method according to this embodiment of the invention.

The fluid channel formation substrate (chip) 12 that constitutes an ink jet type recording head according to the invention is made of a silicon single crystal substrate having a surface 110. As illustrated in FIG. 3, the fluid channel formation substrate 12 is formed in accordance with the following procedures: firstly, a plurality of pre-separation fluid channel formation substrates 12 are formed as a single piece as a whole on a fluid channel formation substrate wafer 100, which is a silicon wafer having a thickness of, for example, approximately 400 μm, that is, the pressure generation chambers 11, and other structures, are formed by performing anisotropic wet-etching on the fluid channel formation substrate wafer 100, and thereafter, the fluid channel formation substrate wafer 100 is separated by cutting them along boundary lines (cutting plane lines) shown in dotted lines in the figure.

In this embodiment of the invention, firstly, a laser beam such as a YAG laser is irradiated on the boundary lines (cutting plane lines) around each area 101, which will constitute the fluid channel formation substrate 12 upon completion on the fluid channel formation substrate wafer 100, while concentrating a beam at a convergence point focused inside the fluid channel formation substrate wafer 100, and then, as illustrated in FIGS. 4A and 4B, fragile parts 103 are formed with a predetermined width in the fluid channel formation substrate wafer 100 while leaving connecting parts 102 at the surface layer portion of one side of the fluid channel formation substrate wafer 100 which the laser beam 200 is irradiated on. In other words, the fragile parts 103 are formed by irradiating the laser beam 200 at a predetermined condition while converging the beam inside the fluid channel formation substrate wafer 100 so as to generate multi-photon absorption inside the fluid channel formation substrate wafer 100.

It should be noted that, the fragile part 103 is an area where the fluid channel formation substrate wafer 100 is subjected to property modification through irradiation of the laser beam 200, where it refers to a crack area at which a plurality of minute cracks are present, a melt-processing area which is in a melted state or in a re-solidified state after melting, and so forth. Each area 101 of the fluid channel formation substrate wafer 100 is substantially disconnected from adjacent one because of the existence of the fragile part 103. In other words, each area 101 of the fluid channel formation substrate wafer 100 is substantially connected to adjacent one by means of the connecting part 102 only. Sometimes, a part of the fragile part 103 peels off when forming the fragile part 103, however, there is not any problem even if it happens.

Although it depends on various conditions of the laser beam 200 such as the output level, the scanning rate, etc., thereof, the fragile part 103, which is formed through irradiation of the laser beam 200, is formed only in the neighborhood of the convergence point in any case. Accordingly, as illustrated in FIGS. 4A and 4B, the fragile part 103 is formed by scanning the laser beam a plural number of times while changing the position P of the convergence point thereof in a thickness direction of the fluid channel formation substrate wafer 100 at the same area on a cutting plane line. Although the number of times of scanning depends on the thickness of the fluid channel formation substrate wafer 100, in this embodiment of the invention, for example, the fragile part 103 is formed by 10-times scanning executions of the laser beam 200 at a scanning speed of approximately 300 mm/s.

As described above, according to an embodiment of the invention, the fragile parts 103 are formed on the cutting plane lines of the fluid channel formation substrate wafer 100 with a predetermined width in the fluid channel formation substrate wafer while leaving connecting parts 102 at the surface layer portion of one side of the fluid channel formation substrate wafer 100 which the laser beam 200 is irradiated on. That is, the fragile part 103 is formed by irradiating the laser beam 200 with its point of convergence being targeted inside the fluid channel formation substrate wafer 100. Although it is also conceivable to form the fragile part 103 by irradiating the laser beam 200 from a side at which the fragile part is exposed, such an implementation is not preferable in a practical sense because there is a possibility that a part of the fragile part 103 peels off during the irradiation of the laser beam 200 to become a foreign object. When the connecting part 102 and the fragile part 103 are formed at each predetermined position in the film thickness direction of the fluid channel formation substrate wafer 100 by the above irradiation method, it is possible to separate the fluid channel formation substrate wafer 100 in a relatively easy manner with a good performance/quality through a process described later, and in addition thereto, almost in no cases, debris of minute crack particles and so on will be formed during a separation process to become a foreign object (particle) that adheres to the fluid channel formation substrate wafer 100.

It is preferable that the thickness “d” of the connecting part 102, which is left when forming the fragile part 103, should be as thin as possible (refer to FIG. 3). That is, the thickness of the connecting part 102 should be as thin as possible while it must be thick enough so that each area 101 of the fluid channel formation substrate wafer 100 will not be disconnected from other parts during a head production process. More specifically, it is preferable that the thickness “d” of the connecting part 102 be 30 μm or less. Since the fragile part 103 is formed by irradiating the laser beam 200 onto the fluid channel formation substrate wafer 100, the width thereof tends to be relatively narrow; and herein, it is preferable that the width of the formed fragile part be as narrow as possible. More specifically, it is preferable that the width of the fragile part 103 be 15 μm or less.

When the fragile part 103 and the connecting part 102 are formed respectively with the dimensions as described above, it is possible to separate the fluid channel formation substrate wafer 100 with a further better performance/quality through a process described later.

After the formation of the fragile part 103 and the connecting part 102 as described above, as illustrated in FIG. 5A, for example, a protective film 110 that consists of silicon dioxide (SiO₂) is formed on a surface of the fluid channel formation substrate wafer 100, and it is subjected to patterning into a predetermined pattern, and subsequently, the fluid channel formation substrate wafer 100 is subjected to etching while using the protective film 110 as a mask, thereby forming a fluid channel such as the pressure generation chamber 11, etc., in each area 101 of the fluid channel formation substrate wafer 100. By this means, the plurality of pre-separation fluid channel formation substrates 12 are formed as a single piece as a whole on the fluid channel formation substrate wafer 100. Next, as illustrated in FIG. 5B, the protective film 110 formed on the surface of the fluid channel formation substrate wafer 100 is removed by using an etchant such as fluorinated acid (HF), and so forth.

Thereafter, the fluid channel formation substrate wafer 100 is separated into a plurality of fluid channel formation substrates 12 by applying an external force thereto. It should be noted that a method for applying an external force to the fluid channel formation substrate wafer 100 is not limited to any specific approach; as an example thereof, it is just enough to use “expandling”, etc., to apply an external force to the fluid channel formation substrate wafer. By this means, as illustrated in FIG. 5C, the fluid channel formation substrate wafer is separated into segments along the fragile part 103, that is, the connecting part 102 is broken (cut into segments), thereby forming the plurality of the fluid channel formation substrates 12.

As described above, according to this embodiment of the invention, the fragile parts 103 are formed to have a predetermined width in the fluid channel formation substrate wafer 100 by irradiating the laser beam 200 thereon while leaving the connecting parts 102 at the surface layer portion of one side of the fluid channel formation substrate wafer 100 which the laser beam 200 is irradiated on. Thereafter, an external force is applied to the fluid channel formation substrate wafer 100 so as to separate it into segments of the fluid channel formation substrates 12. By this means, it is possible to separate the fluid channel formation substrate wafer 100 in a relatively easy manner with a good performance/quality so as to form the fluid channel formation substrates 12. Almost in no cases, any visually perceivable irregularities such as convexes or concaves are observed on the separation surface (section end face) of the fluid channel formation substrates 12 formed according to the above-described separation method.

In addition, as described above, since the fragile part 103 is substantially disconnected from the fluid channel formation substrate wafer 100, any of the fragile parts 103 remaining when separating the fluid channel formation substrate wafer 100 peels off spontaneously when the connecting part 102 is broken (cut into segments). A crack particle that peels off at such an occasion has a diameter of, even at its maximum, approximately 5 μm, which is very small. Therefore, even in a case where such a crack particle settles inside a fluid channel such as a pressure generation chamber, it is possible to easily drain the crack particle from a nozzle by, for example, washing in the fluid channel after production of an ink jet type recording head. Thus, it is possible to prevent any crack particle (foreign object) that might be formed during separation of the fluid channel formation substrate wafer 100 from clogging a nozzle or causing any other similar undesirable effects, which also improves a production yield rate.

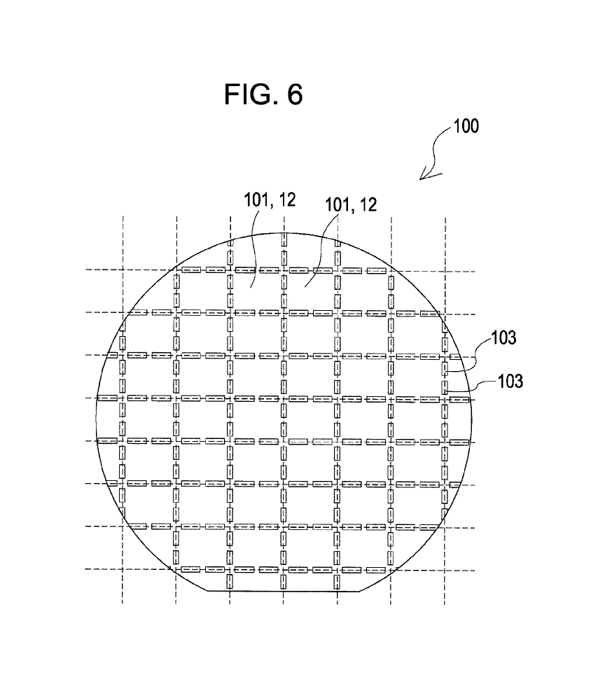

It should be noted that, although the fragile parts 103 are formed in the fluid channel formation substrate wafer 100 by irradiating the laser beam 200 thereon prior to formation of the pressure generation chambers 11, etc., in the fluid channel formation substrate wafer 100 through etching according to this embodiment of the invention, the scope of the invention is in no case limited to such a specific mode of implementation; that is, as a variation of the invention, needless to say, the fragile part 103 may be formed after formation of the pressure generation chambers 11, etc., in the fluid channel formation substrate wafer 100. In addition, although the fragile parts 103 are formed in a serial manner along the cutting plane lines in the fluid channel formation substrate wafer 100 according to this embodiment of the invention, as a variation of the invention, the fragile parts 103 may be formed in an intermittent manner (i.e. in a so-called perforated line pattern) along the cutting plane lines as illustrated in FIG. 6.

### Variant Embodiments

Although one embodiment of the invention is explained above, needless to say, the scope of the invention is in no case limited to such a specific embodiment. For example, although the invention is explained while exemplifying an ink jet type recording head as a typical example of a liquid ejecting head, needless to say, the invention is also applicable to some production other than liquid ejecting head production. The invention provides a method that is particularly suitable to be used when separating a substrate made of a fragile material that is relatively susceptible to fracture such as, other than a silicon wafer, a glass substrate, an MgO substrate, or any other fragile substrate. It should be noted that the type of a laser beam irradiated when forming fragile parts in a substrate has to be selected appropriately in accordance with the material of the substrate.

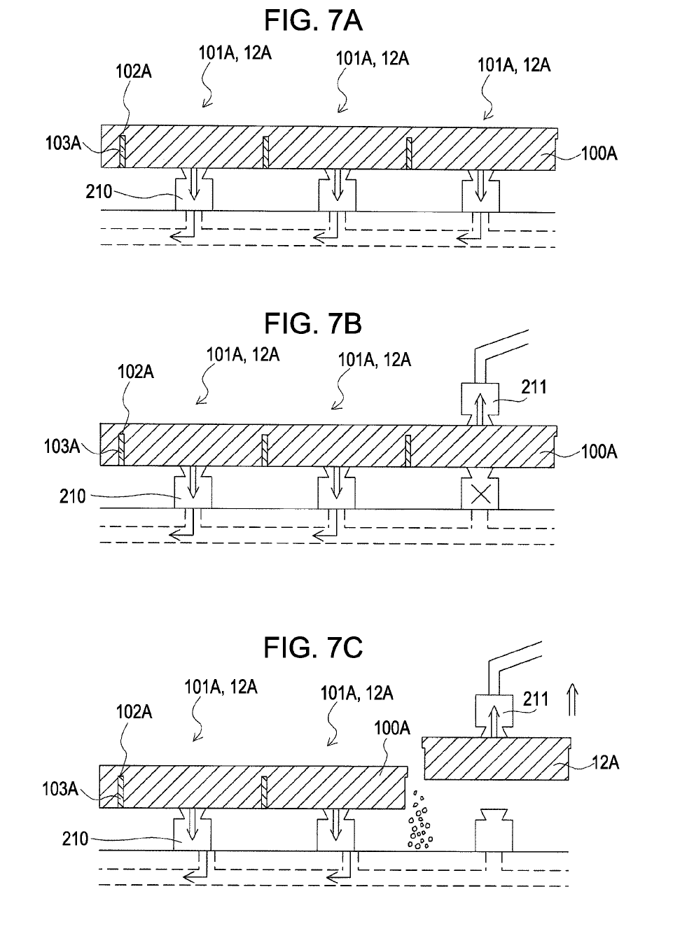

In addition, according to an aspect of the invention, since fragile parts are formed in a substrate, it is possible to separate the substrate into a plurality of chips without fail even when an external force applied to the substrate is relatively weak. For this reason, for example, if a substrate to be separated can be suctioned by a force, it is possible to separate the substrate into a plurality of chips with a good performance/quality also by suctioning and then moving each chip linked to another by a connecting part. More specifically, for example, as illustrated in FIG. 7A, each area 101A (chip 12A) of the substrate 100A in which the connecting parts 102A and the fragile parts 103A are formed is held by a suction force applied from one surface side (bottom surface side according to an exemplary drawing) by means of a suction holding unit 210, which is connected to a vacuum pump, etc. Then, as illustrated in FIG. 7B, each area 101A is suctioned from the other surface side (top surface side according to an exemplary drawing) of the substrate 100A by means of a suction moving unit 211, and the (lower) suction by the suction holding unit 210 corresponding to the currently-suctioned area 101A, that is, the area 101A which is being currently suctioned by the suction moving unit 211, is halted. Finally, as illustrated in FIG. 7C, the suction moving unit 211 is lifted up to separate the connecting part 102A and the fragile part 103A of the substrate 100A by an external force applied to the substrate 100A during the lifting movement, which provides a variant configuration of the invention. That is, it is possible to separate one chip 12A from the substrate 100A with such a variant configuration of the invention.

What is claimed is:

1. A substrate separation method for separating a substrate into a plurality of chips, comprising:
a first step of irradiating a laser beam on boundary lines of each area, which constitutes a chip, of the substrate, while concentrating the beam at a convergence point inside the substrate;
a second step of forming fragile parts with a predetermined width in the substrate while leaving connecting parts only at a surface layer of the substrate at a laser beam irradiation side; and
a third step of separating the substrate into the plurality of chips along the fragile parts by applying an external force to the substrate.

2. The substrate separation method according to claim 1, wherein, in the second step, the fragile parts are formed in a serial manner along the boundary lines of each area, which constitutes a chip.

3. The substrate separation method according to claim 1, wherein, in the second step, the fragile parts are formed in an intermittent manner along the boundary lines of each area, which constitutes a chip.

4. The substrate separation method according to claim 1, wherein, in the second step, the fragile parts are formed such that the thickness of the connecting part is 30 μm or less.

5. The substrate separation method according to claim 1, wherein, in the second step, the fragile parts are formed such that the width of the fragile part is 15 μm or less.

6. The substrate separation method according to claim 1, wherein, in the second step, the fragile parts are formed by scanning the laser beam on the boundary lines a plural number of times while changing the position of the convergence point in a thickness direction of the substrate.

7. A method for producing a liquid ejecting head, the liquid ejecting head having a fluid channel formation substrate in which pressure generation chambers, each of which is communicated with a nozzle and which applies pressure for ejecting droplets from the nozzle, are formed, the liquid ejecting head production method comprising:
forming a plurality of the fluid channel formation substrates on a fluid channel formation substrate wafer as a single piece as a whole; and,
after formation thereof, separating the fluid channel formation substrate wafer into a plurality of the fluid channel formation substrates according to the substrate separation method as set forth in claim 1.
